(19) United States
(12) Patent Application Publication
(10) Pub. No.: US 2024/0086594 A1
(43) Pub. Date: Mar. 14, 2024

(54) DEEP LEARNING METHODOLOGIES FOR SERVER THERMAL DESIGN

(71) Applicant: DELL PRODUCTS L.P., Round Rock, TX (US)

(72) Inventor: Evangelos Koutsavdis, Leander, TX (US)

(73) Assignee: DELL PRODUCTS L.P., Round Rock, TX (US)

(21) Appl. No.: 17/942,436

(22) Filed: Sep. 12, 2022

(51) Int. Cl. G06F 30/27; G06N 3/08

(52) U.S. Cl. CPC G06F 30/27; G06N 3/08

(57) ABSTRACT

A system for designing a component, comprising a component design system operating on a processor that is configured to execute one or more algorithms to generate a digital component design model, a graphic information unitization system operating on the processor that is configured to execute one or more algorithms to receive the digital component design model and to convert it into a format for use with one or more design data attributes and a deep learning system operating on the processor that is configured to execute one or more algorithms to receive the converted digital component design model and the one or more design data attributes and to process the converted digital component design model and the one or more design data attributes using a deep learning algorithm to identify one or more design modifications.

### TECHNICAL FIELD

The present disclosure relates generally to component design methodologies, and more specifically to a component designed using a system and method for server thermal design that utilizes deep learning.

### BACKGROUND OF THE INVENTION

Design of components is frequently limited by the manual design processes that are used, which frequently results in components that are not optimized for an application.

### SUMMARY OF THE INVENTION

A system and method for designing a component is disclosed that includes a component design system operating on a processor that is configured to execute one or more algorithms to generate a digital component design model, such as a stereolithography (STL) file. A graphic information unitization system operating on the processor is configured to execute one or more algorithms to receive the digital component design model and to convert it into a format for use with one or more design data attributes, such as a voxelized format. A deep learning system operating on the processor is configured to execute one or more algorithms to receive the converted digital component design model and the one or more design data attributes and to process the converted digital component design model and the one or more design data attributes using a deep learning algorithm to identify one or more design modifications, such as a component modification that will improve cooling or otherwise result in a lower temperature rise under load conditions.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings may be to scale, but emphasis is placed upon clearly illustrating the principles of the present disclosure. Moreover, in the drawings, like reference numerals designate corresponding parts throughout the several views, and in which:

FIG. 1 is a diagram of a system for manufacturing an optimized component, in accordance with an example embodiment of the present disclosure;

FIG. 2 is a diagram of an algorithm for using deep learning for manufacturing an optimized component, in accordance with an example embodiment of the present disclosure; and

FIG. 3 is a diagram of a component optimization process, in accordance with an example embodiment of the present disclosure.

### DETAILED DESCRIPTION OF THE INVENTION

In the description that follows, like parts are marked throughout the specification and drawings with the same reference numerals. The drawing figures may be to scale and certain components can be shown in generalized or schematic form and identified by commercial designations in the interest of clarity and conciseness.

The time required to design a system or component is often a function of manual activities. One constraint on the design of data processing systems that requires extensive manual activity is the thermal design power (TDP) of the central processing unit, which must be maintained within predetermined limits to prevent excessive temperature rise. The ability to remove heat from a server is a design process that requires extensive manual activity. For example, measurements of temperature rise usually require prototypes that take time and cost to build, because computer-aided design (CAD) processes are not mature enough to allow for a detailed simulation.

The present disclosure recognizes that deep learning can be used to improve the design process for components that have thermal design constraints. For example, artificial neural networks (ANN) models can be trained on existing data to very quickly produce accurate predictions on new input data. The present disclosure applies ANN design techniques and supervised learning to thermal design to optimize the thermal design of such components.

In order to accomplish this objective, the inputs and the outputs of the thermal design problem are converted into a format that is compatible with ANN processing. In one example embodiment, the present disclosure adjusts or modifies certain mathematical weights, such ones that represent geometric inputs or other suitable data, in order to prepare the input/output pairs that will be provided to an ANN.

The present disclosure further utilizes deep learning by applying additional categories of data to the design data that can be analyzed using an ANN. In one example embodiment, simple tabular data such as ambient temperatures, TDP of the CPU or memory, the geometry of the server or other design component, or other suitable data can be used with deep learning. Utilizing two types of inputs such as numerical tabular data and geometry can be accomplished using two different branches or avenues as input data to the ANN.

The geometry can be determined from the output of a CAD design process, which is typically provided in either a proprietary format of the CAD package or in a CAD neutral format, such as Standard for the Exchange of Product Data (STEP) format, a the Parasolid format, the Initial Graphics Exchange Specification (IGES) format, the STL format or other suitable formats. It is possible to convert data files between formats, and the present disclosure uses the STL format in one example embodiment for conversion to a voxelated image for optimized processing by the ANN. A voxel is generally recognized as being a unit of graphical information that defines a point in 3D space, although other suitable types of graphical information can also or alternatively be used in conjunction with the present disclosure. In this regard, the present disclosure essentially converts the geometry of the system or component into an image equivalent and uses conventional ANN image processing, including but not limited to convolutional neural networks (CNNs), in conjunction with additional design data to optimize a design, as opposed to the usual application for image data processing with an ANN to identify the image.

A scaling transformation can be applied to the geometry before the STL file or other design data is converted to a set of voxels. A voxel is the 3D-equivalent of a pixel, where a spatial coordinate that is occupied by the geometry is given a voxel value, and a spatial coordinate that is not occupied by the geometry is given no voxel value. In one example embodiment, the voxel data can be converted to a matrix containing values of only “0” and “1,” where “1” represents the area where a voxel is present and “0” represent an area where no voxel is present (empty space). This matrix can then be processed by “flattening” to optimize input into an ANN, a CNN or other suitable models.

The voxelization process generates a tensor (i.e. matrix data) that can be processed by an ANN, a CNN or in other suitable manners, to apply filters to the data in order to extract patterns and features that become part of the training process. While CNNs are used extensively for image recognition in many applications, the present disclosure recognizes that voxelated CAD data can be used in conjunction with tabular data to train a CNN model in a different manner, for design instead of image recognition. In this manner, the iterative design process can utilize data from other designs to optimize the final system design.

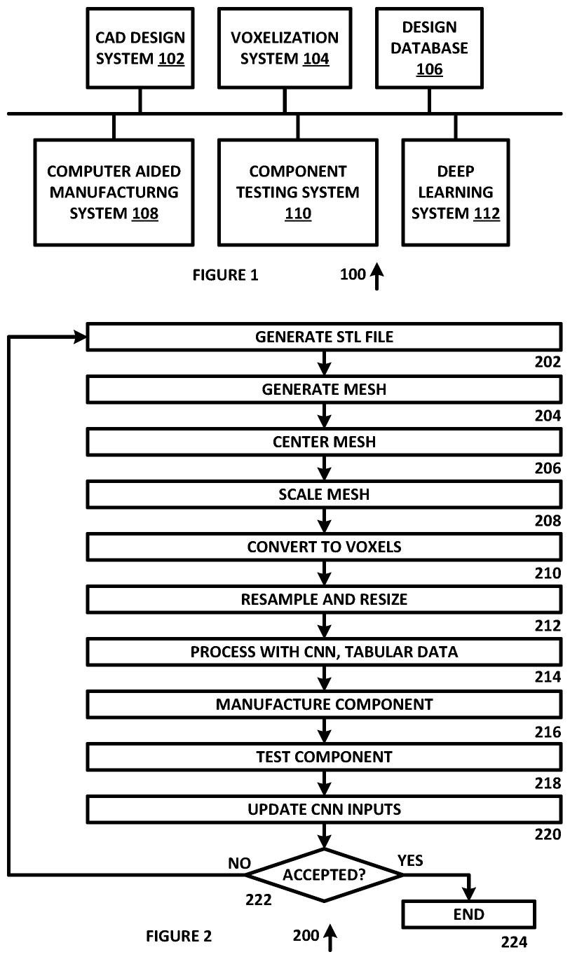

FIG. 1 is a diagram of a system 100 for manufacturing an optimized component, in accordance with an example embodiment of the present disclosure. System 100 includes CAD design system 102, voxelization system 104, design database 106, computer aided manufacturing system 108, component testing system 110 and deep learning system 112, each of which can be implemented in hardware or suitable combination of hardware and software.

CAD design system 102 can be implemented as one or more algorithms that are loaded into a memory device of a data processor and that cause the data processor when executed to generate user interface controls to allow a user to create or modify a system or component design. In one example embodiment, the user can select editing tools to allow the user to create or modify a design by modifying a plurality of line segments, solid shapes, materials, dimensions, finishes or other suitable parameters. CAD design system 102 can generate output data files that can be used to reconstruct the design, such as STEP, Parasolid, IGES, STL or other suitable file formats.

Voxelization system 104 can be implemented as one or more algorithms that are loaded into a memory device of a data processor and that cause the data processor when executed to receive a design data file from CAD system 102 or other suitable systems and to convert the design data file into a voxel file. In one example embodiment, voxelization system 104 can generate a mesh, center the mesh, scale the mesh, convert the CAD design data to voxels, can resample and resize the voxels and can perform other suitable processing.

Design database 106 can be implemented as one or more algorithms that are loaded into a memory device of a data processor and that cause the data processor when executed to select tabular design data associated with a CAD design. In one example embodiment, tabular data can be used for a lower branch of a model that can be implemented as an ANN or in other suitable manners, and voxelated image data can be used for a top branch of a model that can be implemented as a CNN or in other suitable manners, where the combination of the two branches can be used to train a unified model. Likewise, additional branches or configurations can be used. The CNN is not used to recognize an image but rather to utilize the features of the voxelated image for training.

In one example embodiment, the tabular design data can include ambient temperature data, thermal design power of components, geometry of associated components, air flow rates and other suitable data.

Computer aided manufacturing system 108 can be implemented as one or more algorithms that are loaded into a memory device of a data processor and that cause the data processor when executed to receive CAD design data and to control manufacturing processes to manufacture the component or system defined by the CAD design data. In one example embodiment, computer aided manufacturing system 108 can control a 3D printer or other suitable equipment to cause a prototype of a component or system to be fabricated, or can perform other suitable functions.

Component testing system 110 can be implemented as one or more algorithms that are loaded into a memory device of a data processor and that cause the data processor when executed to receive a component or system and can perform automated testing on the component or system. In one example embodiment, component testing system 110 can receive test protocol data and can implement the test protocol, such as to measure temperatures of component parts at different power levels or other suitable test parameters.

Deep learning system 112 can be implemented as one or more algorithms that are loaded into a memory device of a data processor and that cause the data processor when executed to apply voxelated component or system design data and tabular data to a deep learning process. In one example embodiment, an ANN, a CNN or other suitable mathematical learning models can be used to estimate a test response of the voxelated component or system to test conditions. In this example embodiment, the estimated test response can be compared to a measured test response and an error signal can be generated and used to update the deep learning model. The updated deep learning model improves over time as more designs are processed, and thus becomes more accurate.

In operation, system 100 allows CAD design data for a component or a system to be used as input to a deep learning model to estimate the response of the component or system to test conditions, operating conditions or other suitable inputs. In this manner, system 100 allows a component design to be optimized.

FIG. 2 is a diagram of an algorithm 200 for using deep learning for manufacturing an optimized component, in accordance with an example embodiment of the present disclosure. Algorithm 200 can be implemented in hardware or a suitable combination of hardware and software.

Algorithm 200 begins at 202, where an STL file or other suitable CAD data files are generated. In one example embodiment, the CAD data file can be converted to an STL file or other suitable processes can also or alternatively be used. The algorithm then proceeds to 204.

At 204, a mesh is generated. In one example embodiment, the mesh can be used to assign coordinates from a CAD model to a standardized coordinate system or for other suitable processes. The algorithm then proceeds to 206.

At 206, the mesh is centered. In one example embodiment, the mesh can be centered at a location that allows the CAD data to be converted to voxels, processed by a deep learning model or processed in other suitable manners. The algorithm then proceeds to 208.

At 208, the mesh is scaled. In one example embodiment, scaling can be used to increase a resolution, reduce a model size or for other suitable purposes. The algorithm then proceeds to 210.

At 210, the model is converted to voxels. In one example embodiment, each coordinate of the model can be checked to determine whether structure is present, and if structure is present then a voxel vale of “1” or other suitable voxel values can be generated. Likewise, if no structure is present, then a voxel value of “0” or other suitable voxel values can be generated. The algorithm then proceeds to 212.

At 212, the voxelated model is resampled and resized. In one example embodiment, resampling and resizing can be used to place the model into a suitable format for processing with deep learning analysis or in other suitable manners. The algorithm then proceeds to 214.

At 214, the model is processed with deep learning analysis. In one example embodiment, a CNN can be used to process the model and tabular data to generate predicted testing responses, such as predictions of temperature rise under different heat loads and cooling loads, or other suitable data. The algorithm then proceeds to 216.

At 216, the component in manufactured. In one example embodiment, the component can be manufactured manually, can be manufactured using automated manufacturing processes such as 3D printing, or other suitable processes can also or alternatively be used. The algorithm then proceeds to 218.

At 218, the component is tested. In one example embodiment, the component can be tested to generate test data that corresponds to data outputs from the deep learning model or other suitable data. The algorithm then proceeds to 220.

At 220, the CNN inputs are updated with the test results. In one example embodiment, an error signal can be generated that identifies a difference between a predicted test response and a measured test response, or other suitable data can be generated and used to update the CNN inputs. The algorithm then proceeds to 222.

At 222, it is determined whether the design is acceptable. If it is determined that the design is not acceptable, the algorithm returns to 202, otherwise it proceeds to 224 and ends.

In operation, algorithm 200 uses deep learning for manufacturing an optimized component. While algorithm 200 is shown as a flow chart, a person of skill in the art will recognize that it can also or alternatively be implemented in whole or in part using object-oriented programming, ladder diagrams, state diagrams, or other suitable programming paradigms.

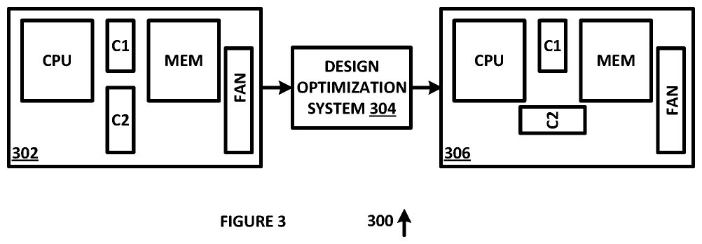

FIG. 3 is a diagram of a component optimization process 300, in accordance with an example embodiment of the present disclosure. Component optimization process 300 uses a manual component design 302 that has not been optimized, which is processed by design optimization system 304. Design optimization system 304 can include one or more components from system 100, and is used to optimize the design to include one or more optimized features that are based on conversion of the design into a voxelized format and processing with a deep learning system, such as a CNN. In particular, the orientation of component C2 has been changed based on the deep learning analysis. The expression of that design modification is apparent upon review of the original design configuration and after the processing of that design, such that the modified design embodies the design modifications, as discussed further herein.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes one or more microcomputers or other suitable data processing units, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections. The term “data” can refer to a suitable structure for using, conveying or storing data, such as a data field, a data buffer, a data message having the data value and sender/receiver address data, a control message having the data value and one or more operators that cause the receiving system or component to perform a function using the data, or other suitable hardware or software components for the electronic processing of data.

In general, a software system is a system that operates on a processor to perform predetermined functions in response to predetermined data fields. A software system is typically created as an algorithmic source code by a human programmer, and the source code algorithm is then compiled into a machine language algorithm with the source code algorithm functions, and linked to the specific input/output devices, dynamic link libraries and other specific hardware and software components of a processor, which converts the processor from a general purpose processor into a specific purpose processor. This well-known process for implementing an algorithm using a processor should require no explanation for one of even rudimentary skill in the art. For example, a system can be defined by the function it performs and the data fields that it performs the function on. As used herein, a NAME system, where NAME is typically the name of the general function that is performed by the system, refers to a software system that is configured to operate on a processor and to perform the disclosed function on the disclosed data fields. A system can receive one or more data inputs, such as data fields, user-entered data, control data in response to a user prompt or other suitable data, and can determine an action to take based on an algorithm, such as to proceed to a next algorithmic step if data is received, to repeat a prompt if data is not received, to perform a mathematical operation on two data fields, to sort or display data fields or to perform other suitable well-known algorithmic functions. Unless a specific algorithm is disclosed, then any suitable algorithm that would be known to one of skill in the art for performing the function using the associated data fields is contemplated as falling within the scope of the disclosure. For example, a message system that generates a message that includes a sender address field, a recipient address field and a message field would encompass software operating on a processor that can obtain the sender address field, recipient address field and message field from a suitable system or device of the processor, such as a buffer device or buffer system, can assemble the sender address field, recipient address field and message field into a suitable electronic message format (such as an electronic mail message, a TCP/IP message or any other suitable message format that has a sender address field, a recipient address field and message field), and can transmit the electronic message using electronic messaging systems and devices of the processor over a communications medium, such as a network. One of ordinary skill in the art would be able to provide the specific coding for a specific application based on the foregoing disclosure, which is intended to set forth exemplary embodiments of the present disclosure, and not to provide a tutorial for someone having less than ordinary skill in the art, such as someone who is unfamiliar with programming or processors in a suitable programming language. A specific algorithm for performing a function can be provided in a flow chart form or in other suitable formats, where the data fields and associated functions can be set forth in an exemplary order of operations, where the order can be rearranged as suitable and is not intended to be limiting unless explicitly stated to be limiting.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A system for designing a component, comprising:
a component design system operating on a processor that is configured to execute one or more algorithms to generate a digital component design model;
a graphic information unitization system operating on the processor that is configured to execute one or more algorithms to receive the digital component design model and to convert it into a format for use with one or more design data attributes; and
a deep learning system operating on the processor that is configured to execute one or more algorithms to receive the converted digital component design model and the one or more design data attributes and to process the converted digital component design model and the one or more design data attributes using a deep learning algorithm to identify one or more design modifications.

2. The system of claim 1 wherein the component design system comprises a computer aided design modeling system.

3. The system of claim 1 wherein the graphic information unitization system comprises a voxelization system.

4. The system of claim 1 wherein the deep learning system comprises an artificial neural network.

5. The system of claim 1 wherein the deep learning system comprises a convolutional neural network.

6. The system of claim 1 wherein the one or more design data attributes comprise an ambient temperature.

7. A method for designing a component, comprising:
generating a digital component design model using a processor operating under the control of one or more algorithms;
converting the digital component design model into a format for use with one or more design data attributes;
processing the converted digital component design model and the one or more design data attributes using a deep learning algorithm; and
identifying one or more design modifications as a result of the processing.

8. The method of claim 7 wherein the digital component design model is generated using a computer aided design modeling system.

9. The method of claim 7 wherein the digital component design model is converted into a format for use with one or more design data attributes using a voxelization system.

10. The method of claim 7 wherein an artificial neural network is used to process the converted digital component design model and the one or more design data attributes.

11. The method of claim 7 wherein a convolutional neural network is used to process the converted digital component design model and the one or more design data attributes.

12. The method of claim 7 wherein the one or more design data attributes comprise an ambient temperature.

13. A component with an optimized design, comprising:
one or more first features designed using a manual design process;
one or more second features having a modified design based on the manual design process after it has been optimized using a deep learning process with one or more design data attributes; and
wherein the deep learning process uses a converted digital component design model.

14. The component of claim 13 wherein the converted digital component design model is generated using a computer aided design modeling system.

15. The component of claim 13 wherein the converted digital component design model is converted into a format for use with one or more design data attributes using a voxelization system.

16. The component of claim 13 wherein an artificial neural network is used to process the converted digital component design model and the one or more design data attributes.

17. The component of claim 13 wherein a convolutional neural network is used to process the converted digital component design model and the one or more design data attributes.

18. The component of claim 13 wherein the one or more design data attributes comprise an ambient temperature.
